(19) United States
(12) Patent Application Publication
(10) Pub. No.: US 2026/0003298 A1
(43) Pub. Date: Jan. 1, 2026

(54) VIEWPORT ASSEMBLY FOR AN EXTREME ULTRAVIOLET LIGHT SOURCE

(71) Applicant: ASML Netherlands B.V., Veldhoven (NL)

(72) Inventors: Dustin Michael Urone, San Diego, CA (US); Lam Nguyen, Oceanside, CA (US); Paul Alexander McKenzie, San Diego, CA (US); Mark Joseph Mitry, San Diego, CA (US); Gregory Theriauit, Encinitas, CA (US); Christopher Liu, San Diego, CA (US)

(21) Appl. No.: 18/869,128

(22) PCT Filed: May 22, 2023
(86) PCT No.: PCT/EP2023/063706

§ 371 Date: Nov. 25, 2024

Related U.S. Application Data
(60) Provisional application No. 63/351,457, filed on Jun. 13, 2022.

(51) Int. Cl. G03F 7/00

(52) U.S. Cl. CPC G03F 7/70941; G03F 7/70033; G03F 7/70841; G03F 7/7085; G03F 7/70958

(57) ABSTRACT

An assembly includes a window useful for optical access to an interior of an extreme ultraviolet (EUV) light source vessel, the window having a transmission band and a protector configured to shield the window from the interior of the EUV light source vessel, the protector comprising a sheet with a surface facing the window across a gap, the sheet having a thermal conductivity in the range of 10 to 2000 W/(m·K). The sheet can be a sapphire sheet, and can have an optical coating on the surface facing the window, the coating reflecting at least some radiation outside the transmission band, and the opposite side of the sheet can be bare sapphire.

### CROSS-REFERENCE TO RELATED APPLICATIONS

This application claims priority of U.S. application 63/351,457 which was filed on Jun. 13, 2022 and which is incorporated herein in its entirety by reference.

### TECHNICAL FIELD

The disclosed subject matter relates to a viewport assembly for an extreme ultraviolet (EUV) light source.

### BACKGROUND

Extreme ultraviolet (“EUV”) light, for example, electromagnetic radiation having wavelengths of around 50 nanometers (nm) or less (also sometimes referred to as soft x-rays), and including light at a wavelength of about 13 nm, can be used in photolithography processes to produce extremely small features on substrates, for example, silicon wafers.

Methods to produce EUV light include, but are not necessarily limited to, converting a material that has an elemental emission line in the EUV range into a plasma state. Suitable materials include, for example, xenon, lithium, and tin. In one such method, often termed laser-produced plasma (“LPP”) or laser-induced breakdown (LIB), the required plasma can be produced by irradiating a target material, for example, in the form of a droplet, stream, or cluster of material, with an amplified light beam that can be referred to as a drive laser. For this process, the plasma is produced in a sealed vessel, for example, a vacuum chamber, and monitored using various types of metrology equipment.

### SUMMARY

In one general aspect, an assembly includes a window configured to allow optical access to an interior of an extreme ultraviolet (EUV) light source vessel, the window having an exterior-facing surface configured to face the exterior of the EUV light source vessel, and an interior-facing surface opposite the exterior-facing surface, the window further having a transmission band encompassing wavelengths of radiation the window can transmit; and a protector configured to shield the window from the interior of the EUV light source vessel, the protector comprising a sheet, the sheet having a window-facing surface and an interior-facing surface opposite the window-facing surface, the window-facing surface facing the interior-facing surface of the window across a gap, the sheet comprising a material having a thermal conductivity in the range of 10 to 2000 W/(m·K).

Implementations can include one or more of the following features: The thermal conductivity of the material can be in the range of 20 to 50 W/(m·K). The transmission band can encompass or be defined as a wavelength band encompassing wavelengths of radiation of which the window can transmit at least 90%. The protector can include a coating on the window-facing surface of the sheet, wherein the coating reflects at least some radiation having wavelengths longer than the wavelengths encompassed by the transmission band. For example, the coating can reflect 50% or more, or even 70% or more, of radiation having wavelengths longer than the wavelengths encompassed by the transmission band and up to 8000 nm. The coating can reflect at least some, or even 50% or more, of radiation having wavelengths shorter than the wavelengths encompassed by the transmission band down to 150 nm. The coating can reflect 50% or more of radiation having wavelengths in a range of 150 to 845 nm and in a range of 1090 to 8000 nm.

Implementations can also include one or more of the following features: the material (of the sheet) can transmit one or more of visible and near-infrared light. The window can be configured to withstand a pressure difference between its interior-facing surface and its exterior-facing surface, even a pressure difference between its interior-facing surface and its exterior-facing surface, as the result of low pressure and/or vacuum at its interior-facing surface, of at least 100 kPa between its two surfaces. The window-facing surface of the sheet can be angled relative to the interior-facing surface of the window. The sheet can include or be formed of sapphire. The window can include or be formed of a glass. The glass can include or can be a borosilicate glass. The borosilicate glass can include or can be Schott N-BK7. The protector can include a coating on the window-facing surface of the sheet, wherein the coating reflects at least some radiation having wavelengths longer than the wavelengths encompassed by the transmission band. The coating can reflect at least some radiation having wavelengths shorter than the wavelengths encompassed by the transmission band.

Implementations can also include one or more of the following features: The interior-facing surface of the sheet can be bare sapphire. The window can include or can be formed of sapphire. The sheet can have a thickness in the range of 2.2 to 3.2 mm. The sheet can also have a thickness in the range of 2.39 to 2.59 mm. The window can have a thickness in the range of 4.0 to 6.5 mm. The window can also have a thickness in the range of 5.9 to 6.1 mm. The assembly can be mounted in an opening defined through a wall of a vacuum chamber of an extreme ultraviolet (EUV) light source, and the vacuum chamber can be under vacuum.

In another general aspect, a metrology apparatus for an extreme ultraviolet (EUV) light source vessel includes a detection module configured to detect light propagating from within the EUV light source vessel and/or a lighting module configured to provide light into the EUV light source vessel, and an assembly arranged along a beam path of the detected light or of the provided light, the assembly including: (1) a window configured to allow optical access to an interior of the EUV light source vessel, the window having an exterior-facing surface configured to face the exterior of the EUV light source vessel, and an interior-facing surface opposite the exterior-facing surface, the window further having a transmission band encompassing wavelengths of radiation the window can transmit, and (2) a protector configured to shield the window from the interior of the EUV light source vessel, the protector including a sheet, the sheet having a window-facing surface and an interior-facing surface opposite the window-facing surface, the window-facing surface facing the interior-facing surface of the window across a gap, the sheet including or being formed of a material having a thermal conductivity in the range of 10 to 2000 W/(m·K).

Implementations can include one or more of the following features: The detection module can include or can be a target detection module. The detection module can include or can be a target imaging module. The lighting module cam include or can be an illumination module configured to probe a target traveling within the EUV light source vessel toward an illumination region. The lighting module can be a target backlighting module configured to probe a target within the EUV light source vessel. The metrology apparatus can include an optical coating on the window-facing surface of the sheet, wherein the optical coating reflects at least some radiation having wavelengths longer than the wavelengths encompassed by the transmission band. The optical coating can reflect at least some radiation having wavelengths shorter than the wavelengths encompassed by the transmission band. The sheet can include or can be formed of sapphire. The window can include or be formed of glass.

In another general aspect, an extreme ultraviolet (EUV) light source can include (1) a vacuum chamber comprising a vacuum chamber wall, the wall defining an opening into an interior of the chamber, (2) a window coupled to the chamber positioned so as to close the opening, the window having an interior-facing facing the interior of the chamber and an exterior-facing surface opposite the interior-facing surface, the window further having a transmission band encompassing wavelengths of radiation the window can transmit, and (3) a protector positioned to shield the window from the interior of the chamber, the protector comprising a sheet, the sheet having a window-facing surface and an interior-facing surface opposite the window-facing surface, the window-facing surface facing the interior-facing surface of the window across a gap, the sheet comprising a material having a thermal conductivity in the range of 10 to 2000 W/(m·K).

Implementations can include one or more of the following features: An optical coating can be on the window-facing surface of the sheet, and the optical coating can reflect at least some radiation having wavelengths longer than the wavelengths encompassed by the transmission band. The optical coating can also reflect at least some radiation having wavelengths shorter than the wavelengths encompassed by the transmission band. The sheet can include or be formed of sapphire. The window can include or be formed of glass. The window can include or be formed of sapphire. The vacuum chamber can be under vacuum.

The details of one or more implementations are set forth in the accompanying drawings and the description below. Other features will be apparent from the description and drawings, and from the claims.

### DRAWING DESCRIPTION

FIG. 1A is a diagrammatic view of an extreme ultraviolet (EUV) light source showing a vessel (such as a vacuum chamber) in which a target location is defined.

FIG. 1B is a close-up view of the viewport assembly within the vessel of the EUV light source of FIG. 1A.

FIGS. 2A and 2B are cross-sectional diagrams of a metrology apparatus of the light source of FIGS. 1A and 1B.

FIG. 3 is a cross-sectional diagrammatic view of a viewport assembly.

FIGS. 4A and 4B are graphs of transmission of example materials used in the viewport assembly.

FIGS. 5A and 5B are cross-sectional diagrams of further aspects of a metrology apparatus.

FIG. 6 is a diagram of an EUV light source together with a lithography apparatus.

### DETAILED DESCRIPTION

An assembly for reducing or minimizing thermal lensing of a viewport assembly of an extreme ultraviolet (EUV) light source is disclosed.

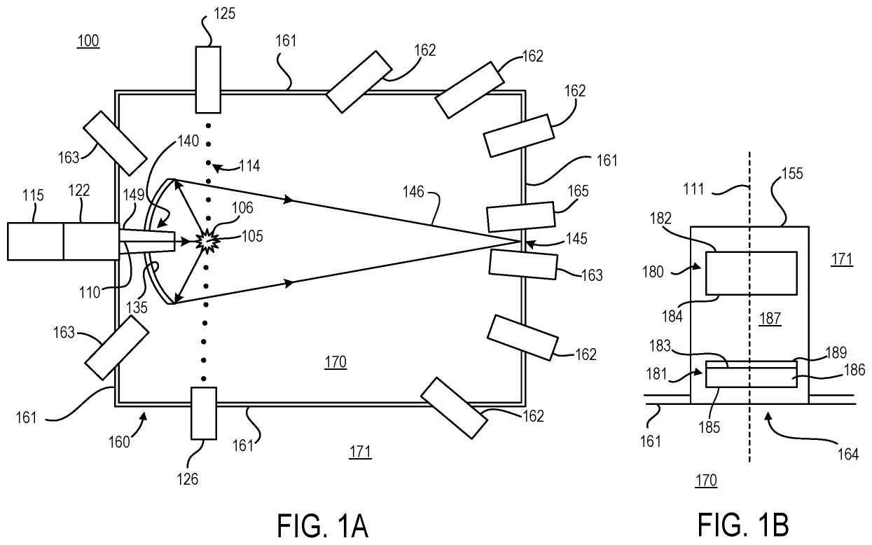

Referring to FIGS. 1A and 1B, an implementation 100 of the EUV light source is shown. A viewport assembly 155 (FIG. 1B) is an observation mechanism that is positioned relative to an opening 164 defined by a wall 161 of a vessel 160. The viewport assembly 155 includes a window 180 through which an interior 170 of the vessel 160 can be viewed or through which light 111 can travel between a component or system at an exterior 171 and the interior 170 of the vessel 160. The vessel 160 can be a chamber that is sealed (and is under vacuum) and has an environmentally controlled interior 170. The viewport assembly 155 can be integrated within any of the elements or modules 162, 163, 165 that are shown as passing through one of the walls 161 of the vessel 160. Details about the elements 162, 163, 165 are provided below.

During operation of the EUV light source, 100, a material such as glass that is used as the material for the window 180 can be heated by incident light 111 absorbed by the viewport assembly 155, that is, light travelling between the exterior 171 and the interior 170 of the vessel 160, or light travelling from the interior 170 of the vessel 160 to the exterior 171. For example, the window material can be heated by absorbing light 111 transmitted from inside the vessel 160. The refractive index of most optical materials varies as a function of temperature. As a result, heating of the window material can cause the window 180 to experience a detrimental effect called thermal lensing, which is a change as a function of temperature in the optical wavefront transmitted by the window. Possible changes to the wavefront include (1) uniform phase shift if the increase in temperature of the window material is uniform across the surface, (2) nonuniform, smoothly varying phase shift causing the addition of optical power if a uniform thermal gradient is produced across the surface of the window material, and (3) irregular phase shift causing a combination of additional optical power and addition of optical aberrations if a non-uniform thermal gradient is created across the window surface.

A protector 181 can be used to shield the window 180 from light 111 coming from inside the vessel 160 and from other conditions in the vessel 160, such as from chemical and/or physical damage and/or from deposition of light-attenuating material. The material of the protector 181 can also be subject to thermal lensing, and such thermal lensing may increase over time as light-attenuating material can be deposited on the protector 181.

The EUV light source 100 operates to produce EUV light 146 by converting a target material, such as tin, that has an emission line in the EUV range, into a “plasma state,” or into a “plasma” 106. In one example technique, the target material is converted into a plasma state by irradiating a target 114 (shown clearly in FIG. 1A) made of the target material with an amplified light beam 110 in the interior 170 of the vessel 160. Conversion to the plasma state 106 releases radiation in the emission spectrum of the material of the target 114. In addition to the desired EUV light 146, the emission spectrum can include deep ultraviolet (DUV) light, visible light, near infrared (NIR) light, and mid-wavelength infrared (MWIR) light. Light having wavelengths in these ranges can propagate toward and arrive at the viewport assembly 155 (positioned in the wall 161) as “incident” light. Further, the interaction between the amplified light beam 110 and the target material 114 can scatter and reflect the amplified light beam 110. Some of the scattered and reflected amplified light beam can also arrive at the viewport assembly 155 as incident light.

One or more viewport assemblies 155 can be used by various metrology and/or lighting modules (such as modules 162, 163, and 165 shown in FIG. 1A) to add light into the interior 170 of the vessel 160 and/or to sense or detect light coming from the interior 170 of the vessel 160 for the purposes of measurement, detection, process monitoring and control, and the like. Thermal lensing, or alteration of the optical properties of components within the viewport assembly 155 by thermal effects, can distort light 111 transmitted into or through the viewport assembly 155 and/or images or light collected through the viewport assembly 155. Because the light beamed through the viewport assembly and light received through the viewport assembly are used for system diagnostics and system control, such as for steering the stream of targets 114, distorted light and/or distorted images formed from the light can reduce the performance of the EUV light source 100 and reduce the amount of or quality of the EUV light 146 that is produced.

The viewport assembly 155 is configured to prevent or reduce the effects of thermal lensing. The viewport assembly 155 includes, in one aspect of the present disclosure, the window 180, which is configured to allow optical access to the interior 170 of the EUV light source vessel 160. The window 180 has an exterior-facing surface 182 and an interior-facing surface 184 and a transmission band encompassing wavelengths of radiation the window 180 can transmit. In an implementation, the transmission band can be defined as a band of wavelengths at which the window 180 can transmit 90% or more of radiation. The viewport assembly 155 further includes a protector 181 configured to shield the window 180 from the interior 170 of the EUV light source vessel 160. The protector 181 includes a sheet 186 having a window-facing surface 183 and an interior-facing surface 185. The window-facing surface 183 faces the interior-facing surface 184 of the window 180 across a gap 187, and the sheet 186 includes a material having a relatively high thermal conductivity, that is, a thermal conductivity in the range of 10 to 2000 W/(m·K), in the range of 30 to 2000 W/(m·K), or in the range of 30 to 50 W/(m·K). The high thermal conductivity of the protector material reduces thermal lensing effects in the protector 181 by rapidly dissipating thermal gradients across the face of the protector 181. In one implementation, the protector 181 includes a coating 189 on the window-facing surface 183 of the sheet 186. The coating 189 reflects at least some radiation having wavelengths longer than the wavelengths encompassed by the transmission band of the window 180, such as by reflecting at least 50% of the incident intensity of the reflected radiation having wavelengths longer than the wavelengths encompassed by the transmission band of the window 180. The reflected radiation reduces a thermal load on the window 180 that would otherwise be caused by at least partial absorption of the radiation reflected by the coating 189, thus reducing or eliminating thermal lensing effects at the window 180. During operation of the EUV source 100, thermal lensing in the viewport assembly 155 can reduce the efficiency of source operation by causing optical disturbances in the operation of various metrology and/or lighting modules, 162, 163, 165, used for operational control. By reducing the effects of thermal lensing, the viewport assembly 155 also can allow the EUV light source 100 to produce more EUV light 146, such as by running the plasma conversion process at a higher rate, while also reducing the chance of system failure or performance degradation from an increase in thermal effects that would otherwise occur.

A description of the components of the EUV light source 100 is initially described before providing a more detailed description of the viewport assembly 155.

As shown in FIG. 1A, the EUV light source 100 generates EUV light 146 by irradiating a target 114 at a target location 105 with an amplified light beam 110 that travels along a beam path toward the target location 105. The target location 105, which is also referred to as the irradiation site, is within the interior 170 of the vessel 160, which can be a vacuum chamber 160. FIG. 1A shows the path of the targets 114 in a plane of the page. However, the path of the targets 114 can be into or out of the plane of the page at any angle relative to the plane of the page. Thus, for example, the path of the targets 114 can travel into or out of the page, such as in a plane that includes the path of amplified light beam 110 and is perpendicular to the plane of the page. When the amplified light beam 110 strikes a target 114 in the target location 105, a target material within the target 114 is converted into a plasma state 106 that has an element with an emission line in the EUV range. The created plasma 106 has certain characteristics that depend on the composition of the target material within the target 114. These characteristics can include the wavelength of the EUV light produced by the plasma 106 and the type and amount of debris released from the plasma 106.

The EUV light source 100 also includes a target material delivery system 125 that delivers, controls, and directs the targets 114, with each target 114 being in the form of a liquid droplet, a liquid stream, solid particles or clusters, solid particles contained within liquid droplets or solid particles contained within a liquid stream. The EUV light source 100 further includes a target catcher 126 positioned to receive unused targets and/or some remains of used targets. Each of the targets 114 includes a target material such as, for example, water, tin, lithium, xenon, or any material that, when converted to a plasma state, has an emission line in the EUV range. For example, the element tin can be used as pure tin (Sn); as a tin compound, for example, SnBr₄, SnBr₂, SnH₄; as a tin alloy, for example, tin-gallium alloys, tin-indium alloys, tin-indium-gallium alloys, or any combination of these alloys. The target or targets 114 can also include impurities such as non-target particles. Thus, in the situation in which there are no impurities, the target or targets 114 are made up of only the target material. The target or targets 114 are delivered by the target material delivery system 125 into the interior 170 of the vessel 160 and to the target location 105.

The EUV light source 100 includes a drive laser system 115 that produces the amplified light beam 110 due to a population inversion within a gain medium or mediums of the laser system 115. The drive laser system 115 includes a beam delivery system including a beam transport system and a focus assembly 122. The beam transport system and the focus assembly 122 steer and modify the amplified light beam 110 as needed and focus the amplified light beam 110 to the target location 105. The term “amplified light beam” encompasses one or more of: light from the laser system 115 that is merely amplified but not necessarily a coherent laser oscillation and light from the laser system 115 that is amplified and is also a coherent laser oscillation.

The optical amplifiers in the laser system 115 can include as a gain medium a filling gas that includes CO₂ and can amplify light at a wavelength of between about 9100 and about 11000 nanometers (nm), and, in particular, at about 10600 nm, at a gain greater than or equal to 1000. Suitable amplifiers and lasers for use in the laser system 115 can include a pulsed laser device, for example, a pulsed, gas-discharge CO₂ laser device producing radiation at about 9300 nm or about 10600 nm, for example, with DC or RF excitation, operating at relatively high power, for example, 10 kW or higher and high pulse repetition rate, for example, 50 kHz or more. The optical amplifiers in the laser system 115 can also include a cooling system such as water that can be used when operating the laser system 115 at higher powers.

The EUV light source 100 includes a collector mirror 135 having an aperture 140 to allow the amplified light beam 110 to pass through and reach the target location 105. The collector mirror 135 can be, for example, an ellipsoidal mirror that has a primary focus at the target location 105 and a secondary focus at an intermediate location 145 (also called an intermediate focus) where EUV light 146 can be output from the EUV light source 100 and can be input to, for example, an integrated circuit lithography tool (not shown in FIG. 1A). The EUV light source 100 can also include an open-ended, hollow cone 149 (for example, a gas cone) that tapers toward the target location 105 from the collector mirror 135 to reduce the amount of plasma-generated debris that enters the focus assembly 122 while allowing the amplified light beam 110 to reach the target location 105. For this purpose, a gas flow can be provided in the cone 149 that is directed toward the target location 105.

The EUV light source 100 can include one or more target detection and sensing modules 162 and one or more light sources 163 to provide illumination for use by the target detection and sensing modules 162. The target detection and sensing modules 162 can provide an output indicative of the position and velocity of a target 114, for example, relative to the target location 105 to allow for controlling the operation of one or more of the target material delivery system 125, the drive laser system 115, and the focus assembly 122 to adjust the timing of pulses of the amplified light beam 110 and the location and/or focal power of a beam focal spot to cause a focused pulse of the amplified light beam 110 to meet the target or targets 114 at the target location 105 for production of the EUV light 146.

Additionally, the EUV light source 100 can include a light source detector or detectors 165 that measures one or more EUV light parameters, including but not limited to, pulse energy, energy distribution as a function of wavelength, energy within a particular band of wavelengths, energy outside of a particular band of wavelengths, and angular distribution of EUV intensity and/or average power. Information from the light source detector 165 can be, used, for example, in controlling and optimizing parameters such as the timing and focus of the pulses of the amplified light beam 110 to properly intercept the targets 114 in the right place and time (within the target location 105) for effective and efficient production of EUV light 146.

Thus, in summary, the EUV light source 100 produces an amplified light beam 110 that is directed as a train of pulses along the beam path to irradiate the target 114 at the target location 105 to convert the target material within the target 114 into plasma 106 that emits light in the EUV range (the EUV light 146). The amplified light beam 110 operates at a particular wavelength (that is also referred to as a source wavelength) that is determined based on the design and properties of the drive laser system 115.

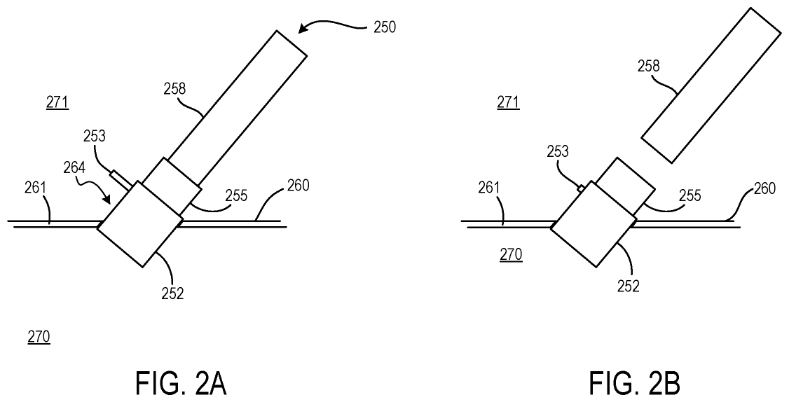

FIG. 2A shows a side view of a wall 261 of an example vessel 260 (which can be a vacuum chamber 260). The vessel 260 can be similar to the vessel 160 discussed above with respect to FIG. 1A. During use, the vessel 260 is sealed such that an interior space 270 of the vessel 260 is maintained as a controlled environment such as a vacuum.

The interior 270 of the vessel 260 and/or objects therein is or are illuminated, monitored, and/or observed with a metrology apparatus 250. The metrology apparatus 250 may take the form a light source or a detection apparatus, such as any of (1) the light source detector or detectors 165, (2) the target detection and sensing modules 162, or (3) the one or more light sources 163 of FIG. 1A, for instance. The metrology apparatus 250 includes a valve assembly 252, a viewport assembly 255 (which is an implementation of the viewport assembly 155), and a metrology or illumination module 258. The metrology apparatus 250 is mounted in an opening 264 that passes through the wall 261 of the vacuum chamber 260 to form a passage from an exterior 271 of the vacuum chamber 260 to the interior 270. During use, the valve assembly 252 and the viewport assembly 255 are coupled together and aligned with the metrology or illumination module 258 to allow the metrology or illumination module 258 to observe or illuminate in or into the interior 270. The valve assembly 252 includes a gate valve 253 that, when closed (FIG. 2B), allows the viewport assembly 255 to be removed from the valve assembly 252 for replacement, adjustment, or cleaning without disturbing a vacuum in the interior 270.

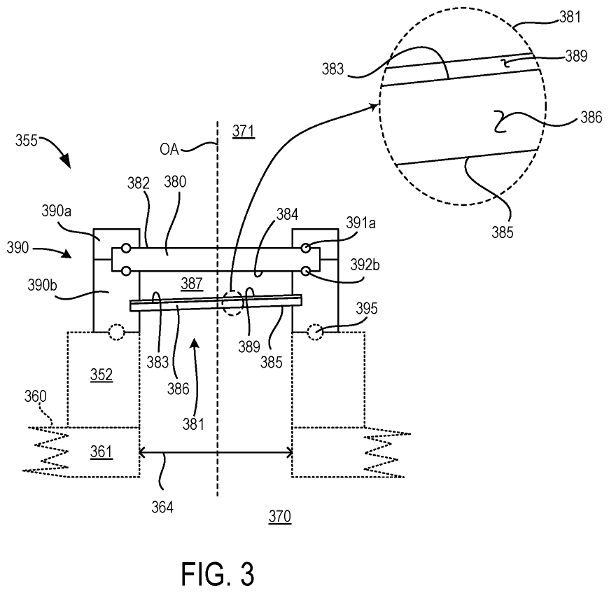

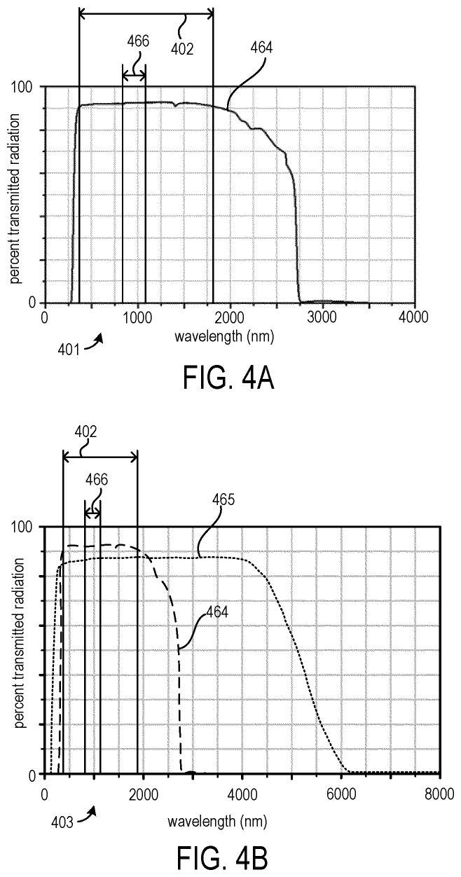

FIG. 3 shows a diagrammatic cross section of an implementation of viewport assembly 255 of FIG. 2 in the form of viewport assembly 355. The viewport assembly 355 includes a window 380 configured to allow optical access to the interior 170 of an extreme ultraviolet (EUV) light source vessel 160 (of FIGS. 1A, 1B, 2A, 2B). The window 380 has an exterior-facing surface 382 configured to face the exterior 371 of the EUV light source vessel 160, and an interior-facing surface 384 opposite the exterior-facing surface 382. The window 380 has a transmission band encompassing wavelengths of radiation the window 380 can transmit (discussed below with respect to FIG. 4A).

The viewport assembly 355 further includes a protector 381 configured to shield the window 380 from the interior 370 of the EUV light source vessel 160. The protector 381 includes a sheet 386 having a window-facing surface 383 and an interior-facing surface 385 opposite the window-facing surface 383. The window-facing surface 383 faces the interior-facing surface 384 of the window 380 across a gap 387. The sheet 386 is made of a material having a thermal conductivity in the range of 10 to 2000 Watts/(meter·Kelvin) (W/(m·K)), or in the range of 20 to 50 W/(m·K). As shown, the window-facing surface 383 of the sheet 386 can be angled relative to the interior-facing surface 384 of the window 380, or can be non-perpendicular to an optical axis OA of the viewport assembly 355, to reduce or avoid back reflection.

Using a high thermal conductivity material for the sheet 386 reduces thermal lensing in the sheet 386 and consequently reduces thermal lensing in the protector 381. Materials having high thermal conductivity and good optical transmission include sapphire and diamond among others. Currently commercially available diamond sheets tend to scatter light having wavelengths near 1000 nm, and some light used for illumination and/or sensing within the EUV light source 100 can be at or near 1000 nm in wavelength. For this reason, sapphire can be a preferred material in the sheet 386 in such EUV light sources.

In implementations, the window 380 can be sealed between halves 390a, 390b of a sleeve 390 by seals such as O-rings 391a, 391b. With the O-rings 391a, 391b or other appropriate sealing, the window 380 is configured to withstand a pressure difference between its interior-facing surface 384 and its exterior-facing surface 382. For example, the window 380 can be configured to withstand a pressure difference between its interior-facing surface 384 and its exterior-facing surface 382, as the result of low pressure and/or vacuum at its interior-facing surface, of at least 100 kiloPascals (kPa).

The window 380 can be made of or include a glass, such as a borosilicate glass. The borosilicate glass can be Schott N BK7, for example.

FIG. 4A is a graph 401 of a transmission curve 464 showing percent transmitted radiation on the vertical axis as a function of wavelength in nanometers (nm) on the horizontal axis for Schott N BK7 or equivalent glass, for an uncoated sheet having a 10 mm thickness. As can be seen in the transmission curve 464, the glass can transmit 90% or more of radiation having wavelengths from about 375 nm to about 1800 nm. A transmission band 402 (of the window 180, 380), defined as a band of wavelengths at which the window can transmit 90% or more of radiation, shown in FIG. 4A, thus extends from about from about 375 nm to about 1800 nm.

FIG. 4B is a graph 403 of transmission curve 465 of optical sapphire for a 10 mm uncoated sheet, sapphire being one of the materials useful as the sheet 386 of the protector 381. The transmission curve 465 is shown as a percentage of radiation transmitted as a function of wavelength in nanometers (nm). The glass transmission curve 464 and the associated transmission band 402 (of the window 180, 380) of FIG. 4A are also shown in FIG. 4B for comparison. As can be seen from a comparison of transmission curves 464 and 465, sapphire transmits a wider range of wavelengths than glass. Although the sheet 386 of the protector 381 resists thermal lensing due to its high thermal conductivity, the window 380, if made of glass, does not have high thermal conductivity, so it is desirable to limit the energy absorbed by the window 380.

Accordingly, in implementations, the protector 381 further includes the coating 389 on the window-facing surface 383 of the sheet 386. The coating 389 reflects at least some radiation having wavelengths longer than the wavelengths encompassed by the transmission band of the window 380.

As can be seen in FIGS. 4A and 4B, the transmission of the glass material of this implementation decreases from around 90% at about 1800 nm to essentially zero at around 2750 nm and above. Sapphire, however, as seen in FIG. 4B, is still relatively highly transmissive at 2750 nm and even longer wavelengths. Thus, it is important to reflect at least some radiation having wavelengths longer than about 1800 nm in order to prevent or reduce thermal lensing in the window 380 when the window is made of glass. For example, the coating 389 can reflect 50% or more, or even 70% or more, of radiation having wavelengths longer than the wavelengths encompassed by the transmission band of the window 380, and up to as high as 8000 nanometers (nm).

In additional aspects, the coating 389 can also reflect at least some radiation having wavelengths shorter than the wavelengths encompassed by the transmission band. For instance, the coating can reflect 50% or more of radiation having wavelengths shorter than the wavelengths encompassed by the transmission band, down to as short as 150 nm.

It might be thought preferable to have the coating 389 positioned on the interior-facing surface 385 of the sheet 386, rather than on the window-facing surface 383, since the coating 389 can then potentially reflect some radiation which can be absorbed at least in part by the sheet 386. But the protector 381 faces a thermally, physically, and chemically challenging environment in the interior 370 of the vacuum chamber 360. For example, hydrogen gas flows can be used in the vacuum chamber 160 (360) to cool internal surfaces and/or to protect internal surfaces of the walls 161 (361) of the chamber 160 (360) from deposition of target material. The hydrogen in the gas flows can become activated or ionized by the energy(ies) released inside the vacuum chamber 160 (360), and such activated or ionized hydrogen can damage some materials and/or surfaces facing the interior 170 (370) of the vacuum chamber 160 (360). To protect the coating 389 from the environment present on the interior 170 (370) of the chamber 160 (360) during operation of the EUV light source 100, according to one aspect, the coating 389 is positioned on the window-facing surface 383 of the sheet 386. The interior-facing surface 385 can be bare sapphire, which has good chemical, physical, and thermal resistance to the environment in the interior 170 (370) of the vacuum chamber 160 (360) during operation of the EUV light source 100.

According to another aspect, the material of the sheet 386 transmits one or more of visible and near-infrared light and/or the coating 389 also transmits one or more of visible and near-infrared light. For example, the sheet 386 and the coating 389 transmit light having wavelengths used in illumination and/or observation within the vacuum chamber 160 (360), such as light having wavelengths within a “metrology band” 466 indicated in FIGS. 4A and 4B. The metrology band 466 can extend, for example, from about 800 nm to about 1000 nm.

In another aspect, the sheet 386 is thinner than the window 380, the thickness being measured along the normal to the surfaces of the sheet 386 and the widow 380. Having the thickness of the sheet 386 relatively small reduces the amount of radiation absorbed by the sheet 386, reducing thermal lensing of the sheet 386 by reducing the absorbed energy available to create a thermal gradient. Thermal lensing effects in a sheet or other element having a given thermal gradient are generally proportional to the thickness or optical path length in the element, so having the thickness of the sheet 386 relatively small with resulting relatively short optical path length reduces thermal lensing effects for this reason as well. Having the thickness of the window 380 relatively larger than the thickness of the sheet 386 allows the window 380 to provide the pressure resistance mentioned above. For example, the sheet 386 can have a thickness in the range of 2.2 to 3.2 millimeters (mm), 2.2 to 2.8 mm, or 2.39 to 2.59 mm. In contrast, the window 380 can have a thickness in the range of 4.0 to 6.5 mm, 5.5 to 6.5 mm, or 5.9 to 6.1 mm.

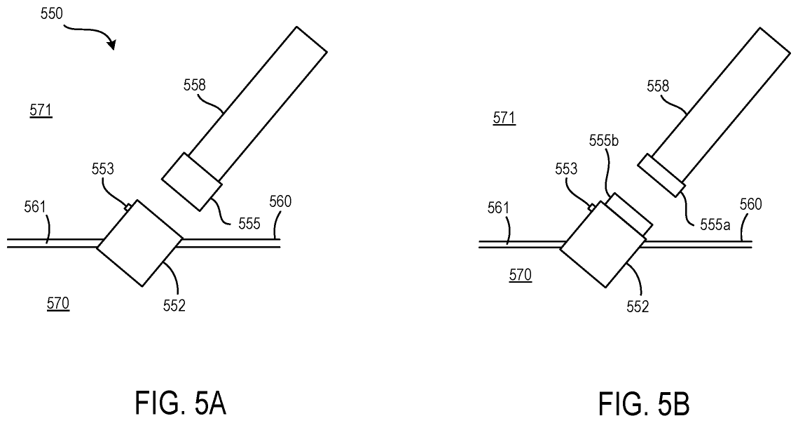

With reference to FIG. 5A, in another aspect, a metrology apparatus 550 for use in an extreme ultraviolet (EUV) light source (such as the EUV light source 100) includes a detection module 558 configured to detect light propagating from within the EUV light source vessel 560, and/or a lighting module 558 configured to provide light into the EUV light source vessel 560. The metrology apparatus 550 also includes a viewport assembly 555 arranged along a beam path of the detected light or of the provided light. With reference to FIG. 3, the viewport assembly 555 is designed like the viewport assembly 355 and therefore includes a window 380 configured to allow optical access to an interior 570 of the EUV light source vessel 560. Like the viewport assembly 355, the window 380 has an exterior-facing surface 382 configured to face the exterior 571 of the EUV light source vessel 560, and an interior-facing surface 384 opposite the exterior-facing surface 382. The window 380 further has a transmission band encompassing wavelengths of radiation the window can transmit. The viewport assembly 555 further includes a protector 381 configured to shield the window 380 from the interior 570 of the EUV light source vessel 560. The protector 381 includes a sheet 386 having a window-facing surface 383 and an interior-facing surface 385 opposite the window-facing surface. The window-facing surface 383 faces the interior-facing surface 384 of the window 380 across a gap 387. The sheet 386 is made of a material having a thermal conductivity in the range of 10 to 2000 W/(m·K). In this aspect, as shown in FIG. 5A, the viewport assembly 555 remains attached or integrated with the metrology module 558 when the metrology module 558 is detached from a valve assembly 552. As mentioned above, prior to removing the viewport assembly 555 and the metrology module 558a, gate valve 553 in the valve assembly 552 can be closed in order to preserve a vacuum or low-pressure environment in the interior 570 of the vessel 560.

In various implementations, the metrology module 558 of the metrology apparatus 550 can function as a target detection module, or a target imaging module, or an illumination module configured to probe a target traveling within the EUV light source vessel 560, or a target backlighting module configured to probe a target within the EUV light source vessel 560.

In another aspect represented in FIG. 5B, the viewport assembly 555 can itself be divided into a window-containing structure 555a and a protector-containing structure 555b, and the two structures 555a and 555b can be separated, with the protector-containing structure remaining with the valve assembly 552 and the window-containing structure remaining with the metrology module 558 when the metrology module is detached from the valve assembly 552.

In another aspect with reference to FIGS. 1A, 1B, and 3, an EUV light source 100 includes a vacuum chamber 160, 360 including a vacuum chamber wall 161, 361, the wall defining an opening 364 into an interior 370 of the chamber. A window 380 is coupled to the chamber 360 and positioned so as to close the opening 364. The window 380 has an interior-facing surface 384 facing the interior 370 of the chamber 360 and an exterior-facing surface 382 opposite the interior-facing surface 384. The window 380 further has a transmission band encompassing wavelengths of radiation the window 380 can transmit, such as, for example, the portions of the transmission curve of FIG. 4A above 90%. The EUV light source 100 further includes a protector 381 positioned to shield the window 380 from the interior 370 of the vacuum chamber 360. The protector 381 includes a sheet 386 having a window-facing surface 383 and an interior-facing surface 385 opposite the window-facing surface 383. The window-facing surface 383 faces the interior-facing surface 384 of the window 380 across a gap 387. The sheet 386 is made of a material having a thermal conductivity in the range of 10 to 2000 W/(m·K).

In further aspects, the window-facing surface 383 of the sheet 386 has an optical coating 389 thereon, and the optical coating 389 reflects at least some radiation having wavelengths longer than the wavelengths encompassed by the transmission band of the window 380. The optical coating 389 can also reflect at least some radiation having wavelengths shorter than the wavelengths encompassed by the transmission band. The sheet 386 can include or be made of sapphire. The window 380 can include or be made of glass.

In another aspect, the window 380 can (also) include or be made of sapphire, if desired.

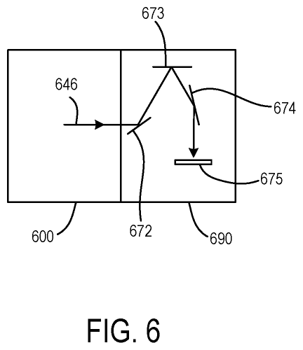

FIG. 6 is a diagram showing an EUV light source 600 which can be an EUV light source having any of the EUV light source vessels 160, 260, 360, 560 disclosed herein. The EUV light source 600 is positioned together with an EUV lithography exposure apparatus 690. The lithography exposure apparatus 690 receives EUV light 646 produced by the EUV light source 600 and reflects it in one or more illumination mirrors 672 so as to illuminate a reflective pattern or reticle 673. EUV light reflected from the pattern or reticle 673 is further reflected and reduced by one or more reducing mirrors 674 and irradiated on a substrate or wafer 675 (or on one or more photosensitive layers on the substrate or wafer 675) to allow the formation of patterned structures on the substrate or wafer 675.

To review and point out some advantages of the disclosed viewport assembly 155, 355, 555, the high thermal conductivity of the material of the sheet 186, 386 reduces thermal lensing of the sheet 186, 386. The high thermal conductivity of the window 180, 380, if sapphire is used in the window, reduces thermal lensing of the window. Alternatively, or in addition, the optical coating 189, 389 on the sheet 186, 386 prevents or reduces thermal lensing of the window 180, 380, even if glass is used in the window, by reflecting at least some radiation that would otherwise be absorbed at least partially by the window.

Positioning the optical coating 189, 389 on the window-facing surface 383 of the sheet 186, 386 protects the optical coating from some chemical, physical, and thermal effects present in the interior 170, 370 of the vacuum chamber 160, 360 during operation of the EUV light source 100.

Keeping the sheet 186, 386 relatively thin reduces the amount of radiation absorbed by the sheet 186, 386, further reducing any thermal lensing effects. The window 180, 380 can be relatively thick, allowing sufficient strength to resist a pressure differential between the interior 170, 370 and the exterior of the vacuum chamber 160, 360.

Having a gap 187, 387 between the protector 181, 381 and the window 180, 380 helps thermally insulate the window 180, 380 from the protector 181, 381. In some aspects, and with reference to FIG. 3, the protector 381 is not sealed in the sleeve 390, which allows the gap 387 to have a vacuum (or a very low pressure) similar to or equal to the interior 370 of the vacuum chamber 360 during use, contributing to the thermal isolation of the window 380 from the protector 381, and allowing the sheet 386 to be thin, since it does not need to withstand a pressure differential.

The embodiments can be further described using the following clauses:
1. An assembly comprising:
a window configured to allow optical access to an interior of an extreme ultraviolet (EUV) light source vessel, the window having an exterior-facing surface configured to face the exterior of the EUV light source vessel, and an interior-facing surface opposite the exterior-facing surface, the window further having a transmission band encompassing wavelengths of radiation the window can transmit; and
a protector configured to shield the window from the interior of the EUV light source vessel, the protector comprising a sheet, the sheet having a window-facing surface and an interior-facing surface opposite the window-facing surface, the window-facing surface facing the interior-facing surface of the window across a gap, the sheet comprising a material having a thermal conductivity in the range of 10 to 2000 W/(m·K).
2. The assembly of clause 1 wherein the thermal conductivity of the material is in the range of 20 to 50 W/(m·K).
3. The assembly of clause 1 wherein the transmission band is a wavelength band comprising wavelengths of radiation of which the window can transmit at least 90%.
4. The assembly of clause 1 wherein the protector further comprises a coating on the window-facing surface of the sheet, wherein the coating reflects at least some radiation having wavelengths longer than the wavelengths encompassed by the transmission band.
5. The assembly of clause 1 wherein the protector further comprises a coating on the window-facing surface of the sheet and the coating reflects 50% or more of radiation having wavelengths longer than the wavelengths encompassed by the transmission band and up to 8000 nm.
6. The assembly of clause 1 wherein the protector further comprises a coating on the window-facing surface of the sheet and the coating reflects 70% or more of radiation having wavelengths longer than the wavelengths encompassed by the transmission band and up to 8000 nm.
7. The assembly of clause 1 wherein the protector further comprises a coating on the window-facing surface of the sheet and the coating reflects 50% or more of radiation having wavelengths longer than the wavelengths encompassed by the transmission band and up to 8000 nm and reflects 50% or more of radiation having wavelengths shorter than the wavelengths encompassed by the transmission band down to 150 nm.
8. The assembly of clause 1wherein the protector further comprises a coating on the window-facing surface of the sheet, wherein the coating reflects at least some radiation having wavelengths longer than the wavelengths encompassed by the transmission band and the coating further reflects at least some radiation having wavelengths shorter than the wavelengths encompassed by the transmission band.
9. The assembly of clause 1 wherein the protector further comprises a coating on the window-facing surface of the sheet, wherein the coating reflects at least some radiation having wavelengths longer than the wavelengths encompassed by the transmission band and the coating reflects 50% or more of radiation having wavelengths in a range of 150 to 845 nm and in a range of 1090 to 8000 nm.
10. The assembly of clause 1 wherein the material transmits one or more of visible and near-infrared light.
11. The assembly of clause 1 wherein the window is configured to withstand a pressure difference between its interior-facing surface and its exterior-facing surface.
12. The assembly of clause 1 wherein the window is configured to withstand a pressure difference between its interior-facing surface and its exterior-facing surface, as the result of low pressure and/or vacuum at its interior-facing surface, of at least 100 kPa between its two surfaces.
13. The assembly of clause 1 wherein the window-facing surface of the sheet is angled relative to the interior-facing surface of the window.
14. The assembly of clause 1 wherein the sheet comprises sapphire.
15. The assembly of clause 1 wherein the sheet comprises sapphire and the window comprises a glass.
16. The assembly of clause 1 wherein the sheet comprises sapphire and the glass comprises a borosilicate glass.
17. The assembly of clause 1 wherein the sheet comprises sapphire and wherein the window comprises Schott N-BK7 borosilicate glass.
18. The assembly of clause 1 wherein the sheet comprises sapphire and the window comprises Schott N-BK7 borosilicate glass and the protector further comprises a coating on the window-facing surface of the sheet, wherein the coating reflects at least some radiation having wavelengths longer than the wavelengths encompassed by the transmission band.
19. The assembly of clause 1 wherein the sheet comprises sapphire and the window comprises Schott N-BK7 borosilicate glass, the protector further comprises a coating on the window-facing surface of the sheet, the coating reflects at least some radiation having wavelengths longer than the wavelengths encompassed by the transmission band, and the coating further reflects at least some radiation having wavelengths shorter than the wavelengths encompassed by the transmission band.
20. The assembly of clause 1 wherein the sheet comprises sapphire and the window comprises Schott N-BK7 borosilicate glass, the protector further comprises a coating on the window-facing surface of the sheet, the coating reflects at least some radiation having wavelengths longer than the wavelengths encompassed by the transmission band, and wherein the interior-facing surface of the sheet is bare sapphire.
21: The assembly of clause 1 wherein the sheet comprises sapphire and the window comprises sapphire.
22. The assembly of clause 1 wherein the sheet has a thickness in the range of 2.2 to 3.2 mm.
23. The assembly of clause 1 wherein the sheet has a thickness in the range of 2.39 to 2.59 mm.
24. The assembly of clause 1 wherein the window has a thickness in the range of 4.0 to 6.5 mm.
25. The assembly of clause 1 wherein the window has a thickness in the range of 5.9 to 6.1 mm.
26. The assembly of clause 1 wherein the assembly is mounted in an opening defined through a wall of a vacuum chamber of an extreme ultraviolet (EUV) light source, the vacuum chamber being under vacuum.
27. A metrology apparatus for an extreme ultraviolet (EUV) light source vessel, the metrology apparatus comprising:
a lighting module configured to provide light into the EUV light source vessel and/or a detection module configured to detect light propagating from within the EUV light source vessel; and
an assembly arranged along a beam path of the detected light or of the provided light, the assembly comprising:
a window configured to allow optical access to an interior of the EUV light source vessel, the window having an exterior-facing surface configured to face the exterior of the EUV light source vessel, and an interior-facing surface opposite the exterior-facing surface, the window further having a transmission band encompassing wavelengths of radiation the window can transmit; and
a protector configured to shield the window from the interior of the EUV light source vessel, the protector comprising a sheet, the sheet having a window-facing surface and an interior-facing surface opposite the window-facing surface, the window-facing surface facing the interior-facing surface of the window across a gap, the sheet comprising a material having a thermal conductivity in the range of 10 to 2000 W/(m·K).
28. The metrology apparatus of clause 27 wherein the detection module comprises a target detection module.
29. The metrology apparatus of clause 27 wherein the detection module comprises a target imaging module.
30. The metrology apparatus of clause 27 wherein the lighting module comprises an illumination module configured to probe a target traveling within the EUV light source vessel toward an illumination region.
31. The metrology apparatus of clause 27 wherein the lighting module comprises a target backlighting module configured to probe a target within the EUV light source vessel.
32. The metrology apparatus of clause 27 further comprising an optical coating on the window-facing surface of the sheet, wherein the optical coating reflects at least some radiation having wavelengths longer than the wavelengths encompassed by the transmission band.
33. The metrology apparatus of clause 27 further comprising an optical coating on the window-facing surface of the sheet, wherein the optical coating reflects at least some radiation having wavelengths longer than the wavelengths encompassed by the transmission band and wherein the optical coating further reflects at least some radiation having wavelengths shorter than the wavelengths encompassed by the transmission band.
34. The metrology apparatus of clause 27 wherein the sheet comprises sapphire.
35. The metrology apparatus of clause 27 wherein the sheet comprises sapphire and the window comprises a glass.
36. The metrology apparatus of clause 27 wherein the sheet comprises sapphire and the window comprises sapphire.
37. An extreme ultraviolet (EUV) light source, the EUV source comprising:
a vacuum chamber comprising a vacuum chamber wall, the wall defining an opening therethrough;
a window coupled to the chamber positioned so as to close the opening, the window having an interior-facing surface facing the interior of the chamber and an exterior-facing surface opposite the interior-facing surface, the window further having a transmission band encompassing wavelengths of radiation the window can transmit; and
a protector positioned to shield the window from the interior of the chamber, the protector comprising a sheet, the sheet having a window-facing surface and an interior-facing surface opposite the window-facing surface, the window-facing surface facing the interior-facing surface of the window across a gap, the sheet comprising a material having a thermal conductivity in the range of 10 to 2000 W/(m·K).
38. The EUV light source of clause 37 further comprising an optical coating on the window-facing surface of the sheet, wherein the optical coating reflects at least some radiation having wavelengths longer than the wavelengths encompassed by the transmission band.
39. The EUV light source of clause 37 further comprising an optical coating on the window-facing surface of the sheet, wherein the optical coating reflects at least some radiation having wavelengths longer than the wavelengths encompassed by the transmission band and wherein the optical coating further reflects at least some radiation having wavelengths shorter than the wavelengths encompassed by the transmission band.
40. The EUV light source of clause 37 wherein the sheet comprises sapphire.
41. The EUV light source of clause 37 wherein the sheet comprises sapphire and the window comprises a glass.
42. The EUV light source of clause 37 wherein the sheet comprises sapphire and the window comprises sapphire.
43. The EUV light source of clause 37 wherein the vacuum chamber is under vacuum.

The above-described implementations and other implementations are within the scope of the following claims.

1. An assembly comprising:
a window configured to allow optical access to an interior of an extreme ultraviolet (EUV) light source vessel, the window having an exterior-facing surface configured to face the exterior of the EUV light source vessel, and an interior-facing surface opposite the exterior-facing surface, the window further having a transmission band encompassing wavelengths of radiation the window can transmit; and
a protector configured to shield the window from the interior of the EUV light source vessel, the protector comprising a sheet, the sheet having a window-facing surface and an interior-facing surface opposite the window-facing surface, the window-facing surface facing the interior-facing surface of the window across a gap, the sheet comprising a material having a thermal conductivity in the range of 10 to 2000 W/(m·K).

2. The assembly of claim 1 wherein the thermal conductivity of the material is in the range of 20 to 50 W/(m·K).

3. The assembly of claim 1 wherein the transmission band is a wavelength band comprising wavelengths of radiation of which the window can transmit at least 90%.

4. (canceled)

5. The assembly of claim 1 wherein the protector further comprises a coating on the window-facing surface of the sheet and the coating reflects 50% or more of radiation having wavelengths longer than the wavelengths encompassed by the transmission band and up to 8000 nm.

6. (canceled)

7. The assembly of claim 1 wherein the protector further comprises a coating on the window-facing surface of the sheet and the coating reflects 50% or more of radiation having wavelengths longer than the wavelengths encompassed by the transmission band and up to 8000 nm and reflects 50% or more of radiation having wavelengths shorter than the wavelengths encompassed by the transmission band down to 150 nm.

8. (canceled)

9. The assembly of claim 1 wherein the protector further comprises a coating on the window-facing surface of the sheet, wherein the coating reflects at least some radiation having wavelengths longer than the wavelengths encompassed by the transmission band and the coating reflects 50% or more of radiation having wavelengths in a range of 150 to 845 nm and in a range of 1090 to 8000 nm.

10. (canceled)

11. (canceled)

12. The assembly of claim 1 wherein the window is configured to withstand a pressure difference between its interior-facing surface and its exterior-facing surface, as the result of low pressure and/or vacuum at its interior-facing surface, of at least 100 kPa between its two surfaces.

13. The assembly of claim 1 wherein the window-facing surface of the sheet is angled relative to the interior-facing surface of the window.

14. The assembly of claim 1 wherein the sheet comprises sapphire and the window comprises glass.

15-18. (canceled)

19. The assembly of claim 1 wherein the sheet comprises sapphire and the window comprises Schott N-BK7 borosilicate glass, the protector further comprises a coating on the window-facing surface of the sheet, the coating reflects at least some radiation having wavelengths longer than the wavelengths encompassed by the transmission band, and the coating further reflects at least some radiation having wavelengths shorter than the wavelengths encompassed by the transmission band.

20. The assembly of claim 1 wherein the sheet comprises sapphire and the window comprises Schott N-BK7 borosilicate glass, the protector further comprises a coating on the window-facing surface of the sheet, the coating reflects at least some radiation having wavelengths longer than the wavelengths encompassed by the transmission band, and wherein the interior-facing surface of the sheet is bare sapphire.

21. The assembly of claim 1 wherein the sheet comprises sapphire and the window comprises sapphire.

22. The assembly of claim 1 wherein the sheet has a thickness in the range of 2.2 to 3.2 mm.

23. (canceled)

24. (canceled)

25. The assembly of claim 1 wherein the window has a thickness in the range of 5.9 to 6.1 mm.

26. The assembly of claim 1 wherein the assembly is mounted in an opening defined through a wall of a vacuum chamber of an extreme ultraviolet (EUV) light source, the vacuum chamber being under vacuum.

27. A metrology apparatus for an extreme ultraviolet (EUV) light source vessel, the metrology apparatus comprising:
a lighting module configured to provide light into the EUV light source vessel and/or a detection module configured to detect light propagating from within the EUV light source vessel; and
an assembly arranged along a beam path of the detected light or of the provided light, the assembly comprising:
a window configured to allow optical access to an interior of the EUV light source vessel, the window having an exterior-facing surface configured to face the exterior of the EUV light source vessel, and an interior-facing surface opposite the exterior-facing surface, the window further having a transmission band encompassing wavelengths of radiation the window can transmit; and
a protector configured to shield the window from the interior of the EUV light source vessel, the protector comprising a sheet, the sheet having a window-facing surface and an interior-facing surface opposite the window-facing surface, the window-facing surface facing the interior-facing surface of the window across a gap, the sheet comprising a material having a thermal conductivity in the range of 10 to 2000 W/(m·K).

28. The metrology apparatus of claim 27 wherein the detection module comprises one or more of: a target detection module or a target imaging module.

29. (canceled)

30. (canceled)

31. The metrology apparatus of claim 27 wherein the lighting module comprises a target backlighting module configured to probe a target within the EUV light source vessel.

32. The metrology apparatus of claim 27 further comprising an optical coating on the window-facing surface of the sheet, wherein the optical coating reflects at least some radiation having wavelengths longer than the wavelengths encompassed by the transmission band.

33-36. (canceled)

37. An extreme ultraviolet (EUV) light source, the EUV source comprising:
a vacuum chamber comprising a vacuum chamber wall, the wall defining an opening therethrough;
a window coupled to the chamber positioned so as to close the opening, the window having an interior-facing surface facing the interior of the chamber and an exterior-facing surface opposite the interior-facing surface, the window further having a transmission band encompassing wavelengths of radiation the window can transmit; and
a protector positioned to shield the window from the interior of the chamber, the protector comprising a sheet, the sheet having a window-facing surface and an interior-facing surface opposite the window-facing surface, the window-facing surface facing the interior-facing surface of the window across a gap, the sheet comprising a material having a thermal conductivity in the range of 10 to 2000 W/(m·K).

38-41. (canceled)

42. The EUV light source of claim 37 wherein the sheet comprises sapphire and the window comprises sapphire.

43. (canceled)
